(19) United States
(12) Patent Application Publication
(10) Pub. No.: US 2011/0220173 A1
(43) Pub. Date: Sep. 15, 2011

(54) ACTIVE SOLAR CONCENTRATOR WITH MULTI-JUNCTION DEVICES

(76) Inventor: MICHAEL LEBBY, APACHE JUNCTION, AZ (US)

(21) Appl. No.: 12/720,104

(22) Filed: Mar. 9, 2010

(51) Int. Cl. H01L 31/052; H01L 31/00

(52) U.S. Cl. 136/246; 136/259; 136/255

(57) ABSTRACT

An active solar concentrator including a horizontally oriented structure including light directing portions with partially reflective surfaces directing light vertically impinging thereon into a central area and a solar module positioned in the central area to receive light from the partially reflective surfaces. The light directing portions each including at least one layer of rare earth oxide designed to up-convert light passing therethrough and positioned to receive light directly and/or from an outer light directing portion. The solar module may include a plurality of multi junction solar cells formed on a common substrate.

### FIELD OF THE INVENTION

This invention relates in general to solar cells and the like and more specifically to semiconductor solar cells.

### BACKGROUND OF THE INVENTION

Typically, in the generation of electrical energy from solar energy, bulk silicon is formed into large arrays of wafers or silicon chips having solar cells formed thereon and electrically connected together to collect generated electricity. Generally, the solar cells are single junction devices (i.e. photodiodes or the like) which are relatively inefficient. Further, the spectral range of Si photodiodes is confined to a wavelength range of between 400 nm and approximately 1000 nm. While germanium has much higher solar spectrum absorption (i.e. can potentially access more of the available solar spectrum), it is substantially more expensive than silicon with silicon substrates being 10× to 50× cheaper than germanium substrates. However, even by using silicon substrates, there is a need to increase solar cell efficiency and dramatically reduce costs.

A major cost in the production of solar cells is the single crystal silicon used to form the solar cells. In an effort to reduce the amount of silicon used and, hence, the cell cost, the volume of silicon required is reduced using thin films of silicon on relatively cheaper substrates. The use of cheaper substrates introduced many new problems most of which have been solved by the inventions disclosed in copending United States Patent Application entitled “Thin Film Solar Cell III”, filed on Sep. 20, 2007, bearing Ser. No. 11/858,838, and incorporated herein by reference.

In the prior art, most solar cells used for generation of power from the sun were of the single junction type device. A major limitation of the single junction solar cells is that they have only a small optical energy absorption window in the immediate vicinity of the fundamental energy band gap which can be used advantageously. Because of this small window a large portion of the available power from the solar spectrum is lost. Thus, large quantities of single crystal silicon must be used to form the relatively large single junction devices as well as including additional costly silicon to compensate for the low absorption.

It would be highly advantageous, therefore, to remedy the foregoing and other deficiencies inherent in the prior art.

Accordingly, it is an object of the present invention to provide a new and improved active solar concentrator structure that is more efficient than present devices.

It is a further object of the present invention to provide a new and improved active solar concentrator structure that is much less expensive and which produces more electricity per area.

It is a further object of the present invention to provide a new and improved active solar concentrator structure that includes structure up-converting solar light for increased efficiency.

### SUMMARY OF THE INVENTION

Briefly, to achieve the desired objects and aspects of the instant invention in accordance with a preferred embodiment thereof, provided is an active solar concentrator including a horizontally oriented structure with light directing portions having partially reflective surfaces directing light vertically impinging thereon into a central area. A solar module is positioned in the central area to receive light from the partially reflective surfaces. The solar module may include a plurality of multi junction solar cells preferably formed on a common substrate.

Desired objects and aspects of the instant invention are further achieved in accordance with a preferred embodiment thereof, in which an active solar concentrator includes a base structure with light directing portions surrounding and defining a central area. Each light directing portion includes at least one layer of rare earth oxide designed to up-convert light passing therethrough. Each light directing portion further includes a reflective surface oriented to receive light vertically from above and to redirect the received light horizontally toward the central area. The light directing portions are further positioned around the central area in a generally outwardly radiating orientation with the reflective surfaces of outer light directing portions directing reflected light inwardly toward a next adjacent light directing portion closer to the central area. Each light directing portion receives the inwardly directed light from an adjacent outer light directing portion through the at least one layer of rare earth oxide. A solar module is positioned in the central area to receive light from the partially reflective surfaces and light passing through the rare earth oxide layers.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 illustrates schematically a typical single junction solar cell;

FIG. 2 illustrates a multi junction solar cell;

FIG. 3 illustrates in top plan an electrode pattern and implementation regions in a thin film semiconductor photovoltaic cell;

FIG. 4 illustrates a group of photovoltaic cells, similar to that shown in FIG. 3, interconnected into a photovoltaic module;

FIG. 5 illustrates in block diagram the interconnection of the photovoltaic module of FIG. 4;

FIGS. 6 and 7 illustrate optional layout schemes for photovoltaic modules fabricated on a circular wafer and on a large area rectangular wafer, respectively;

FIG. 8 illustrates manufacturing cost per solar cell versus number of cells per module;

FIG. 9 is a sectional view illustrating one embodiment of an active solar concentrator device in accordance with the present invention;

FIG. 10 is a graphical representation of the distribution band for solar light;

FIG. 11 is a view in top plan, portions thereof removed, of one formation of the active solar concentrator device of FIG. 9;

FIG. 12 is a sectional view illustrating another embodiment of an active solar concentrator device in accordance with the present invention;

FIG. 13 is a view in top plan, portions thereof removed, of one formation of the active solar concentrator device of FIG. 12; and

FIGS. 14, 15, and 16 are simplified side views of various rare earth single crystal up-conversion and/or down-conversion devices for use with any of the multi junction solar cells described herein and/or to provide the rare earth layers of up-conversion material for the light directing portions.

### DETAILED DESCRIPTION OF THE DRAWINGS

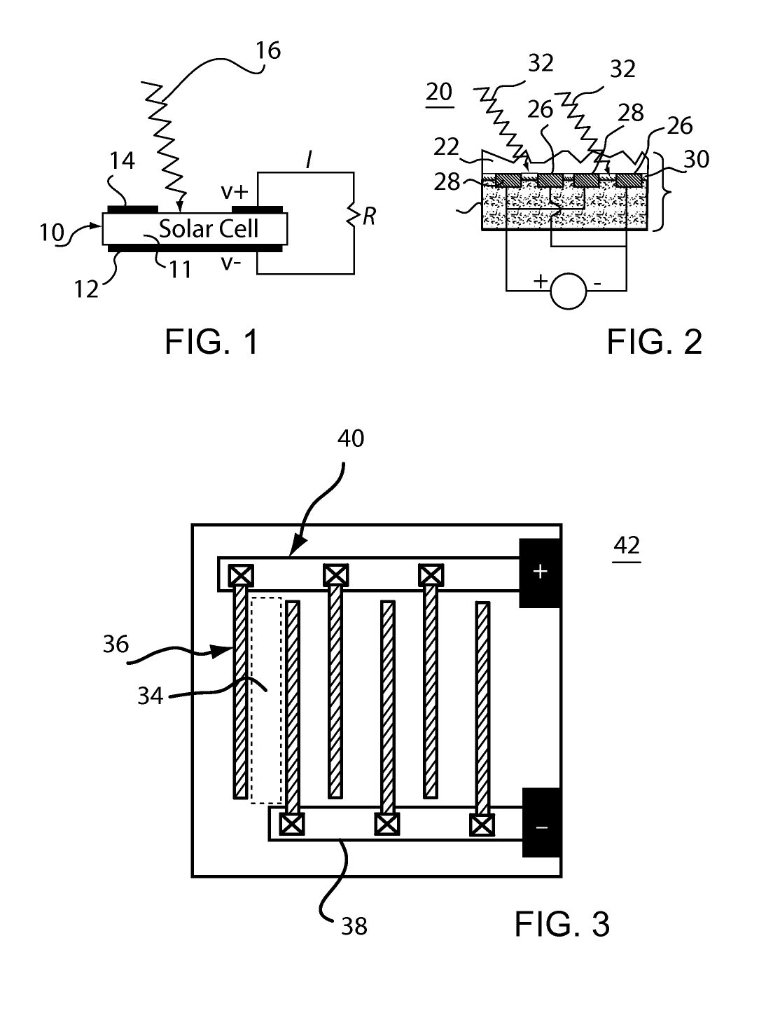

Turning to FIG. 1, a typical single junction and/or bulk silicon solar cell 10 is illustrated. Solar cell 10 includes a body 11 of semiconductor material with one electrical contact 12 on the lower surface and another electrical contact 14 on the upper surface. As light, represented by arrow 16, impinges on the surface of body 11 of cell 10, the photons generate carriers (i.e. holes and electrons) that migrate to electrical contacts 12 and 14 as electrical current. One of the major problems in this construction is that the holes and electrons have a very limited path and tend to rejoin before they reach electrical contacts 12 and 14 if the contacts are spaced too far apart. Clearly, restricting body 11 to a size in which minimum recombinations occur, results in a small optical energy absorption window.

To overcome this and other problems in single junction solar cells, multi junction solar cells were developed as described in the above referenced copending patent application. Examples of such multi junction solar cells are illustrated in FIGS. 2 and 3. In the solar cell illustrated in FIG. 2, designated 20, a thin film layer 22 of single crystal silicon is provided along with an alternative substrate 24 having contacts 26 and 28 formed on the surface thereof. An insulating layer 30 is positioned on the surface of alternative substrate 24 surrounding contacts 26 and 28. Thin film layer 22 is bonded to alternative substrate 24 by insulating layer 30 as explained in detail in the above referenced copending patent application. Contacts 26 and 28 are spaced apart but positioned closely enough to minimize recombination of carriers separated by light 32 impinging on thin film layer 22.

As illustrated in FIG. 3, the different contacts in a solar cell of the type illustrated in FIG. 2 can be electrically connected by connecting the interdigitated contacts 34 and 36 to elongated electrodes 38 and 40. Thus, the structure illustrated in FIG. 3 makes up a multi junction solar cell, designated 42. It will of course be understood that many other embodiments and variations could be devised but the basic concept here is to provide a multi junction solar cell in which the optical energy absorption window is maximized while recombinations of carriers is minimized.

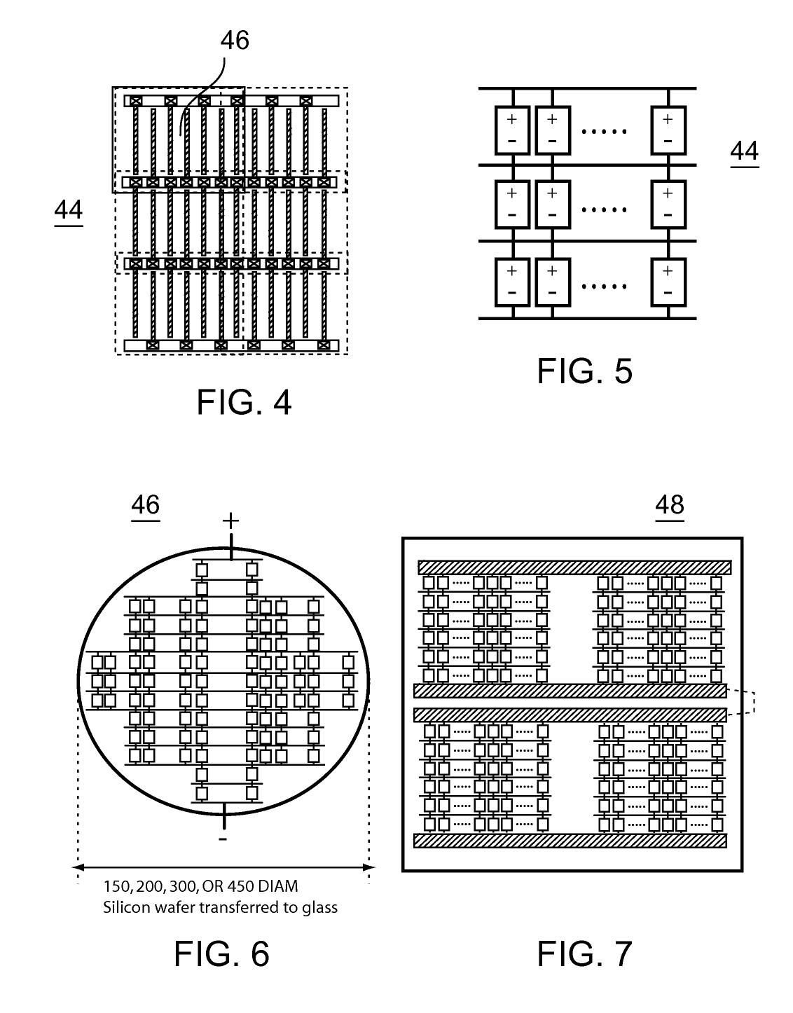

Turning to FIG. 4, a group of multi junction solar cells or photovoltaic cells, similar to cell 42 of FIG. 3, are interconnected into a photovoltaic module 44. Module 44 is illustrated in block diagram in FIG. 5 and, as illustrated, may include any convenient number of cells 42. Referring additionally to FIGS. 6 and 7, a plurality of modules 44 are formed and interconnected on a typical round wafer 46 and on a large rectangular wafer or chip 48, respectively. These are simply two examples of modules that can be formed by combining a plurality or array of photovoltaic cells. It will be understood that the number and position of the cells within a given semiconductor substrate (e.g. wafer of large area chip) or the number of modules and the number of cells in a module will depend upon the specific process and materials being used. It will also be understood that at least one purpose of combining a plurality of photovoltaic cells into a module is to make use of as much of the semiconductor material as practical. Thus, it is presumed that the number of modules on a semiconductor substrate and the number of cells in a module will be selected to form the greatest number of cells practical on a specific substrate.

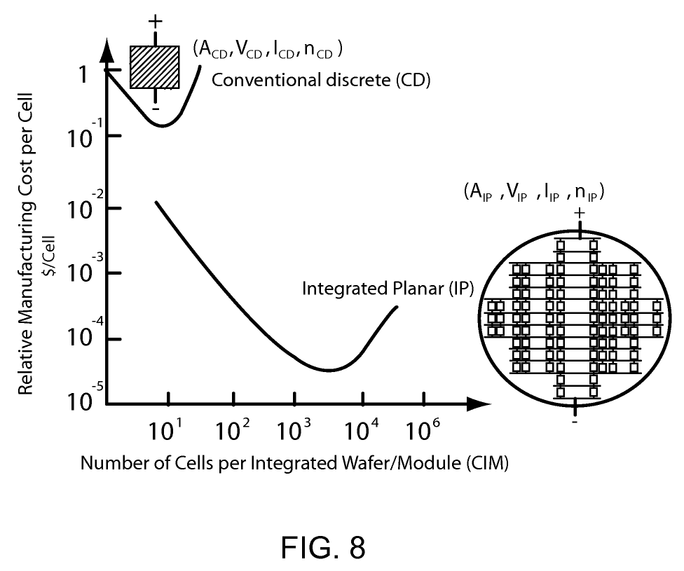

Turning now to FIG. 8, a graph is illustrated showing the manufacturing cost per solar cell versus the number of cells per module. The upper curve illustrates the cost per cell for conventional discrete cells with the discrete manufacturing case shown as prior art approaches to solar cell and module production. The lower curve illustrates the cost per cell for modules of multi junction solar cells fabricated in accordance with the methods described in the above copending patent application. Generally, it is assumed that integrated planar transistor manufacturing paradigms, such as CMOS FETs, are used to minimize the cost per solar cell. The planar integrated manufacturing paradigm allows more cells to be densely packed into a finite area with large improvement in complexity and/or function and reduced module cost.

Turning now to FIG. 9, a sectional view illustrates one embodiment of an active solar concentrator structure 100 in accordance with the present invention. Active solar concentrator structure 100 includes a solar device 102, which is at least one solar cell and preferably a multi junction cell, module, or modules, (hereinafter referred to generically as a “module”) and surrounding light directing portions 103, including partially reflective surfaces 104. Light directing portions 103 with partially reflective surfaces 104 are disposed in a common horizontal plane in a generally outwardly radiating orientation around solar module 102 and spaced apart to collect as much sunlight as possible and direct it horizontally inward onto solar module 102.

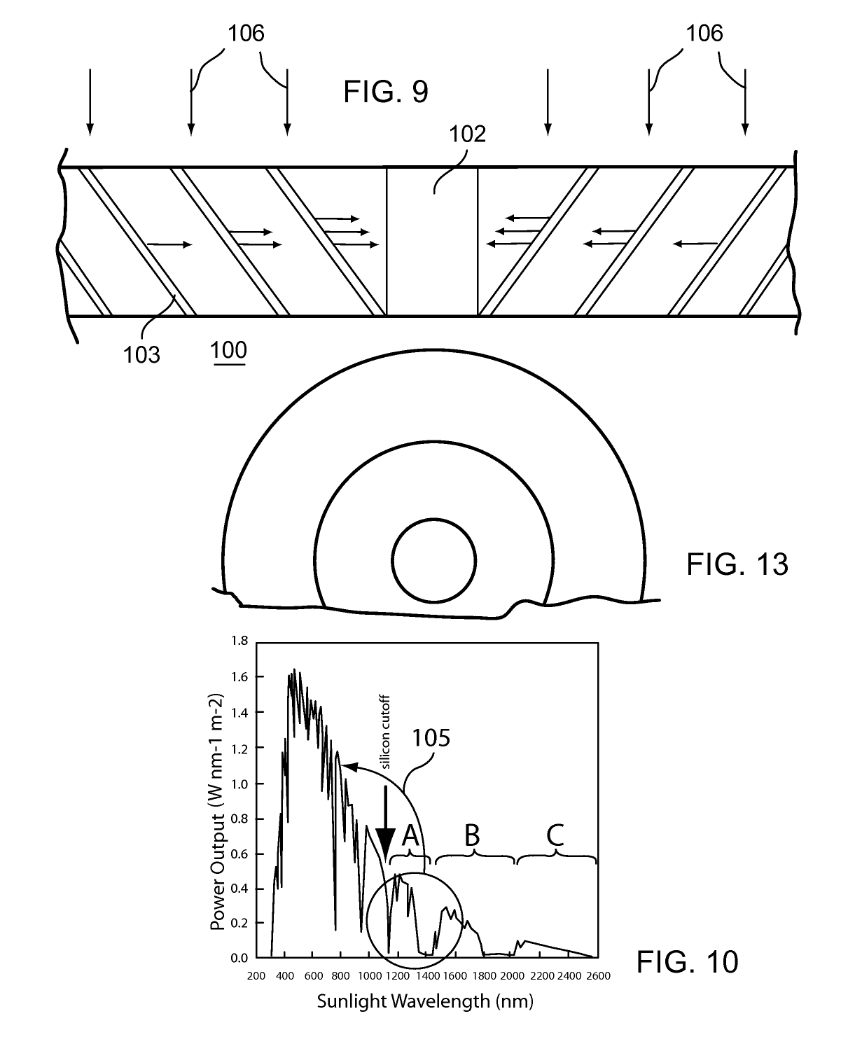

Illustrated in FIG. 10 is a graphical representation of the distribution band for solar light. Generally, solar cells are formed of silicon, which convert light below approximately 1100 nm to electricity. However, as can be seen in the graphical representation, substantial portions of solar light are above 1100 nm. To increase the efficiency of the solar collector, in the preferred embodiment, light directing portions 103 are formed to include a rare earth oxide. Here it should be understood that light directing portions 103 can be formed substantially of a rare earth oxide with a reflecting surface on the outer surface. Light directing portions 103 can also be formed with a layer of rare earth oxide on either or both of the outer surfaces (for example with the reflecting surface buried between rare earth layers). Rare earth oxides provide light up-conversion in ranges from 1100 nm to approximately 1500 nm. As indicated by arrow 105 in FIG. 10, light passing through the rare earth oxide light directing portions 103 is up-converted so that it appears in the bandwidth of the silicon solar cells. Thus previously waste solar light is converted to electricity.

Generally, partially reflective surfaces 104 receive sunlight, represented by arrows 106 and redirect the sunlight at a ninety degree angle inwardly. The front or upwardly directed portions of surfaces 104 are fully reflective while the rear surfaces are fully transparent or conductive to allow light from the outer surfaces 104 to pass through inner surfaces 104 to solar module 102. Also, substantially all of the solar light impinging upon concentrator structure 100 will pass through at least some of the rare earth oxide light directing portions 103 and be up-converted. The amount of up-conversion that occurs will depend somewhat upon the lateral guiding of light in portions 103. The lateral guiding can be enhanced somewhat by the angles included and the thickness of portions 103. Further, it will be understood that sunlight falls substantially equally on every part of surfaces 104 so that light is directed onto solar device 102 substantially equally across the entire area.

As shown, for example, in any of FIGS. 4-7, a multi junction module includes a large number of very small sunlight receiving and converting areas. Thus, while a multi junction module converts sunlight very well if it is simply placed in normal sunlight, the amount of sunlight striking each cell or area is very small. Concentrator 100 greatly increases the amount of sunlight impinging upon each conversion area and, therefore, greatly increases the amount of energy converted. Also, by concentrating the sunlight any specific portion of the sunlight that a solar module may convert (e.g. the lower bandwidth portions of the sunlight) is concentrated to increase the output. While concentrator 100 will operate efficiently with single junction solar cells, it greatly improves the electrical output of multi junction cells formed on a common wafer or substrate.

It can be determined from the above described copending patent application that many of the solar cells disclosed are capable of converting sunlight impinging thereon from either side of the substrate. Thus, solar module 102 in FIG. 9, for example, could be oriented vertically so that sunlight strikes the substrate from both sides. Also, in FIG. 11 concentrator 100 is illustrated as a flat generally square device but it will be understood that any convenient shape, e.g. round, rectangular, triangular, etc., could be used. One advantage of a square or regular sided structure is that they can be easily formed into a continuous pattern of concentrators. Further, in any or all of these structures, solar module 102 might include a number and/or a variety of modules.

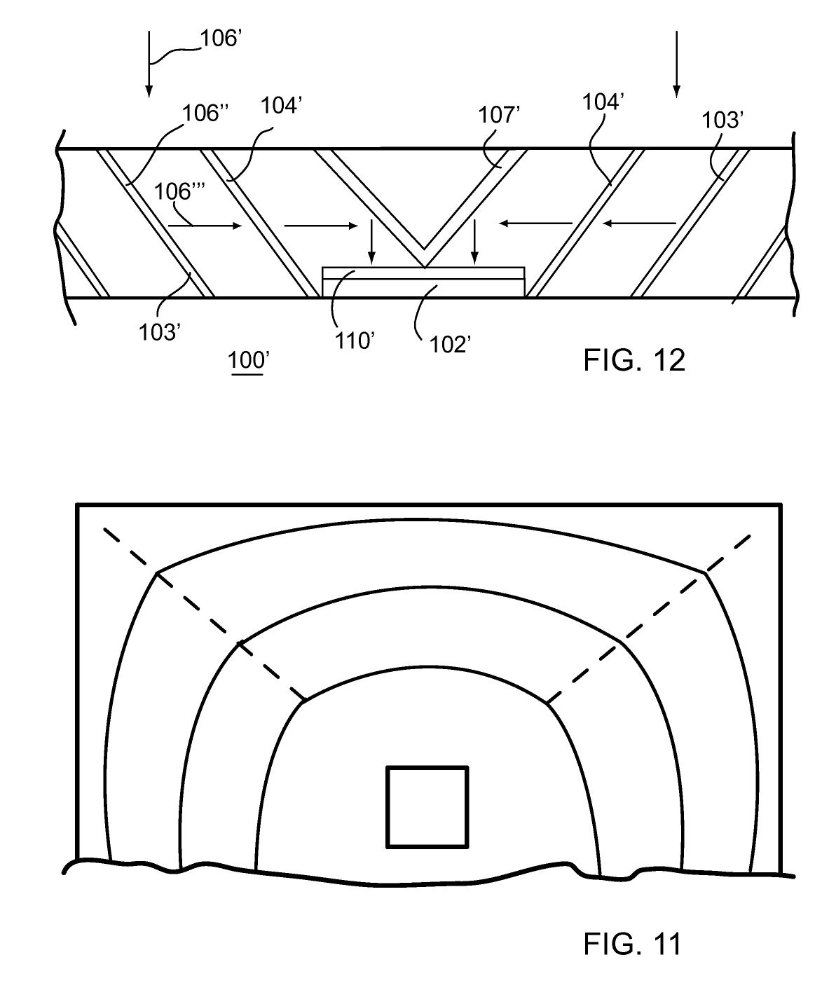

Referring additionally to FIG. 12, a sectional view illustrates another embodiment of an active solar concentrator device 100′ in accordance with the present invention. In this embodiment, components that are similar to components in FIG. 9 are designated with a similar number and a prime (′) is added to indicate the different embodiment. Active solar concentrator device 100′ includes a solar module 102′, which is at least one solar module and preferably a multi junction module and surrounding partially reflective surfaces 104. Partially reflective surfaces 104′ are disposed in a common horizontal plane around solar module 102′ and spaced apart to collect as much sunlight as possible and direct it horizontally inward onto solar module 102′. Also, in FIG. 13 concentrator 100′ is illustrated as a flat generally circular device but it will be understood that any convenient shape, e.g. square, rectangular, triangular, etc., could be used.

In concentrator 100′, solar module 102′ is oriented horizontally and a cone shaped reflector 107′ is positioned directly over solar module 102′. Cone shaped reflector 107′ redirects sunlight, represented by arrows 106′, from partially reflective surfaces 104′ of light directing portions 103′ downward onto the surface of solar module 102′. Thus sunlight collected or concentrated by concentrator 100′ is dispersed evenly over the surface of solar module 102′. Cone shaped reflector 107′ can be partially reflective so that sunlight directly above solar module 102′ pass through cone shaped reflector 107′ and impinges upon solar module 102′. In this fashion all sunlight impinging upon concentrator 100′ would reach solar module 102′ and be converted to electricity.

As explained above in conjunction with FIG. 9, in the preferred embodiment, to increase the efficiency of the solar collector, light directing portions 103′ and cone shaped reflector 107′ are formed to include a rare earth oxide. Rare earth oxides provide light up-conversion in ranges from 1100 nm to approximately 1500 nm. In all of the reflection concentrators disclosed (e.g. concentrator 100′), solar light 106′ impinging upon the concentrator includes X % L>1100 nm (where L is impinging light 106′). After the light passes through a first portion 103′, designated 106″, it includes X/2% L>1100 nm. Further, after the light passes through more concentrators, designated 106′″, it includes X/3% L>1100 nm. That is lateral guiding and up-conversion is enhanced by the angles included and the thickness of portions 103′ and the number of portions 103′ that the light is guided through.

Further, in any or all of the various embodiments including concentrator 100′, a layer of rare earth oxide material, designated 110′ is formed over the surface of solar module 102′. As explained above, lateral guiding and up-conversion is enhanced by the thickness of portion 110′. Further, since up-conversion is increased by the lateral guiding of light through the various rare earth layers, it will be understood that any design devised to increase the length of the light path through any or all of the various layers of rare earth material can substantially improve the efficiency of the concentrator.

Also, concentrator 100 or 100′ can be formed of material that is relatively inexpensive compared to single crystal semiconductor material, such as silicon. For example, most of the structure of concentrator 100, including partially reflective surfaces 104, can be formed of glass or hard plastic. Thus, the amount of sunlight collected and converted by a solar module can be enhanced many fold while reducing the expense to a minimum. Further, in some embodiments, the main structure of concentrator 100 can include light filters or the like at some point in the light path and prior to impinging upon solar module to limit light striking solar module 102 to light that solar module 102 is capable of converting.

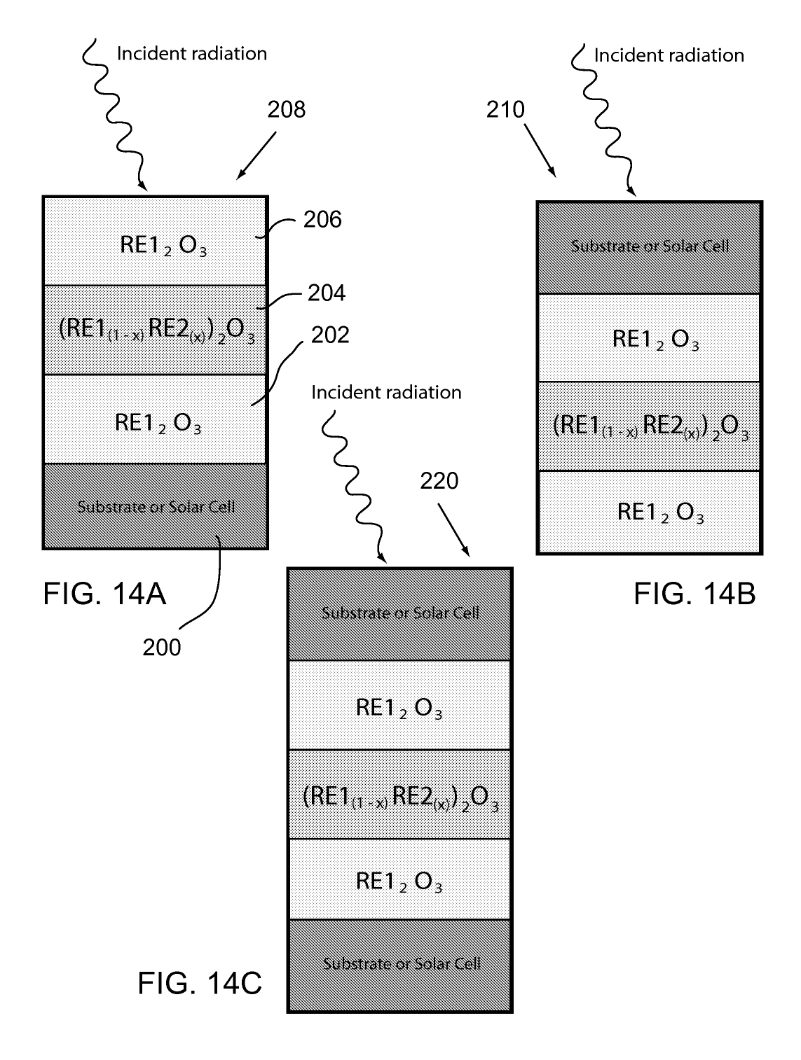

To further enhance solar conversion in any of the solar cells illustrated and explained above, rare earth single crystal up-conversion devices can be incorporated. Several such devices are illustrated in FIGS. 14, 15, and 16. Referring specifically to FIG. 14, a substrate or solar cell 200 is illustrated in FIG. 14A, which may be, for example, a single crystal silicon solar cell that has an optimum performance in the range of 500 nm to 1100 nm of radiation. A first layer 202 of rare earth oxide is deposited on the surface of a substrate or a solar cell 200, a layer 204 of rare earth alloys is deposited on layer 202 and a second layer 206 of rare earth oxide is deposited on the surface of layer 204. Layers 202, 204, and 206 form rare earth single crystal up-conversion device generally designated 208. In this specific embodiment, incident radiation is directed onto the upper surface of layer 206 with radiation approximately in the range of 500 nm to 1100 nm passing through device 208 and impinging upon solar cell 200. In a typical example, device 208 could be incorporated into light directing portions 103 of concentrator 100 or light directing portions 103′ of concentrator 100′, with a thin substrate 200 to allow the passage of light therethrough.

Since the solar spectrum generally has a range from 400 nm to 2500 nm, radiation outside of the range of 500 nm to 1100 nm is wasted or is not utilized to generate electrical energy (see FIG. 10). Device 208 converts at least part of this radiation to a wavelength within the range of 500 nm to 1100 nm (see FIG. 10) where it is used to generate electrical energy. Certain of the rare earths, either alone or in combination with other rare earths, can absorb light or radiation at one wavelength and reradiate or emit the absorbed light at another wavelength. When the incident wavelength is less than the emission wavelength the process is referred to as up-conversion and down-conversion is the process in which the incident radiation is higher than the emitted radiation. Thus, in either process there is some additional radiation within the range from 400 nm to 2500 nm for generating additional electricity.

Turning to FIG. 14B, an embodiment, generally designated 210, is illustrated in which a substrate or solar cell is deposited as a last layer on the surface of the up-conversion and/or down-conversion device. In embodiment 210 the radiation impinges directly on the solar cell and unused radiation passing through the solar cell is converted by the device and re-emitted back into the solar cell.

Turning to FIG. 14C, an embodiment, generally designated 220, is illustrated in which a first substrate or solar cell forms a first layer with an up-conversion and/or down-conversion device deposited thereon and a second substrate or solar cell is deposited as a last layer on the surface of the up-conversion and/or down-conversion device. In embodiment 220 the radiation impinges directly on the first solar cell and unused radiation passing through the solar cell is converted by the device and re-emitted back into either the first solar cell at the top of the stack or the second solar cell at the bottom of the stack. Also, in this embodiment any radiation in the range from 500 nm to 1100 nm that is not absorbed by the first solar cell will pass through the stack and be absorbed by the second solar cell at the bottom thereof.

Generally, the rare earth layers illustrated in FIG. 14 are formed in a single crystal layer that is substantially lattice matched to the underlying layer and especially to the underlying or overlying silicon semiconductor material (e.g. layers 200 and 206). Also, while a rare earth oxide is described it should be understood that in at least some applications a rare earth phosphide, a rare earth nitride, or combinations thereof (e.g. oxynitride, oxyphosphide, etc.) can be used. Thus, the generic term “rare earth insulator” is used to incorporate any rare earth (lanthanide series) with any of oxygen, nitrogen, and/or sulfur.

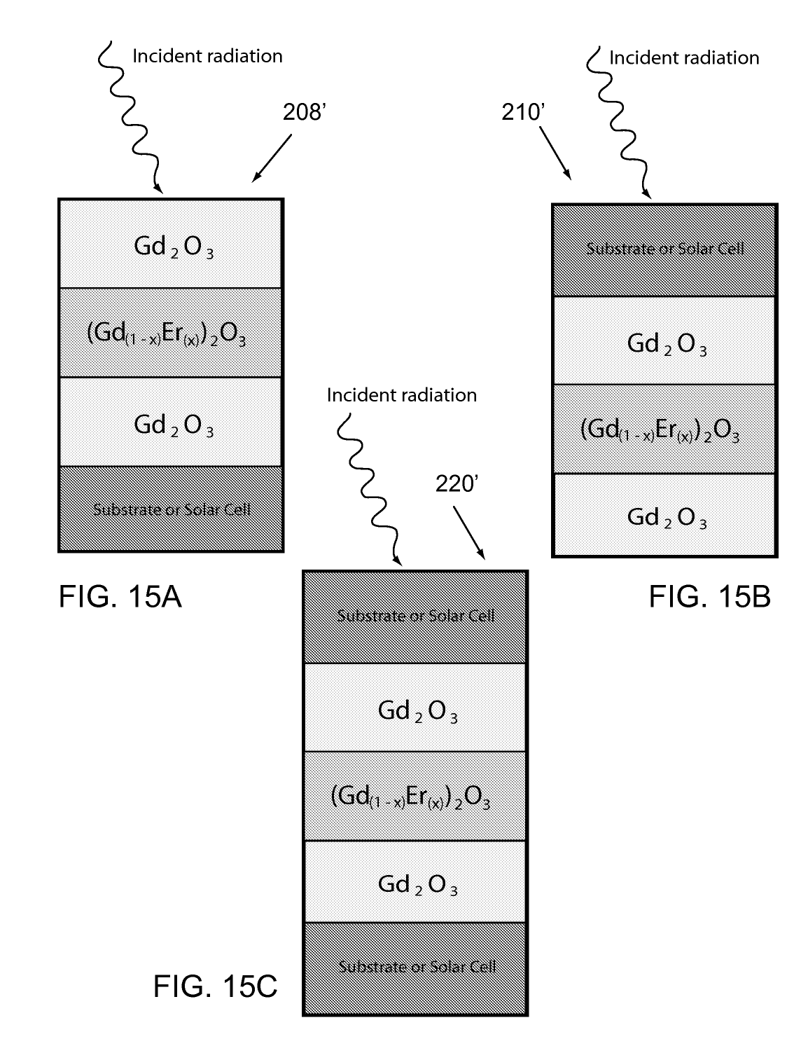

Turning to FIG. 15, specific examples of several rare earth single crystal up-conversion and/or down-conversion devices is illustrated. In FIG. 15A, for example, a device 208′, similar to the device 208 illustrated in FIG. 14, is shown. Device 208′ includes a single crystal silicon solar cell as the base layer. A layer of single crystal Gadolinium oxide (Gd₂O₃) is epitaxially grown on the surface of the single crystal silicon solar cell. A single crystal layer of Gadolinium and Erbium oxide (Gd₍₁₋ₓ₎Er₍ₓ₎)₂O₃) is epitaxially grown on the surface of the single crystal Gadolinium. A layer of single crystal Gadolinium oxide (Gd₂O₃) is epitaxially grown on the surface of the single crystal layer of Gadolinium and Erbium oxide. In FIG. 15B a device 210′, similar to the device 210 illustrated in FIG. 14B, is shown. In device 210′ the single crystal silicon solar cell is epitaxially grown on the surface of the upper single crystal Gadolinium oxide layer. In FIG. 15C a device 220′, similar to the device 220 illustrated in FIG. 14C, is shown. In device 220′ a single crystal silicon solar cell is supplied as the base and a single crystal silicon solar cell is epitaxially grown on the surface of the upper single crystal Gadolinium oxide layer.

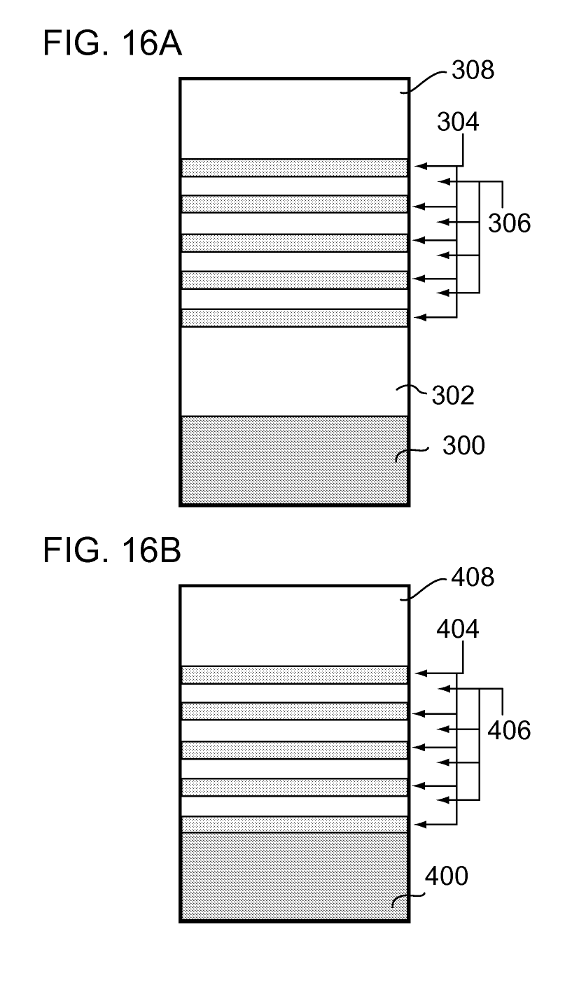

Referring to FIG. 16A a Distributed Bragg Reflector (DBR) is formed on a silicon substrate or solar cell to act as a reflector and ensure that all, or substantially all, incident radiation is absorbed rather than reflected. In this embodiment, a silicon substrate or solar cell 300 is provided and a first crystalline or single crystal layer 302 of Silicon/germanium is epitaxially deposited thereon. The materials of layer 302 are provided in a mix or alloy of Si₍₁₋ₓ₎Ge₍ₓ₎. Preferably, the material of layer 302 is Si_{0.9}Ge_{0.1}. Also, layer 302 is doped to produce one semiconductor conduction type, e.g. p-channel or n-channel.

A plurality of alternating crystalline or single crystal layers 304 of rare earth insulator are disposed between crystalline or single crystal layers 306 of Si₍₁₋ₓ₎Ge₍ₓ₎. Each of the layers 304 and 306 are approximately 1000 angstroms thick and provide strain matching or are substantially crystallographically matched to reduce strain between adjacent layers. Layers 304 and 306 cooperate to form a Distributed Bragg Reflector (DBR) specifically designed to reflect radiation back onto substrate or solar cell 300. For example, each of layers 304 and 306 are generally approximately one fourth wavelength (λ/4) thick at the wavelength of radiation to be absorbed. Also, as explained above, layers 304 can be chosen to up convert or down convert incident radiation to further enhance absorption in substrate or solar cell 300.

A second crystalline or single crystal layer 308 of Silicon/germanium is epitaxially deposited on the upper surface of the DBR. The materials of layer 308 are provided in a mix or alloy of Si₍₁₋ₓ₎Ge₍ₓ₎. Preferably, the material of layer 308 is Si_{0.9}Ge_{0.1}. or a mix commensurate with layer 302 Also, layer 308 is doped, opposite to layer 302, to produce one semiconductor conduction type, e.g. n-channel or p-channel. Thus, layers 302, 304, 306, and 308 form a semiconductor diode that can be used to incorporate the cell into any of the structures illustrated and described above.

Referring to FIG. 16B another embodiment of a Distributed Bragg Reflector (DBR) is formed on a silicon substrate or solar cell to act as a reflector and ensure that all, or substantially all, incident radiation is absorbed rather than reflected. In this embodiment, a silicon substrate or solar cell 400 is provided and is doped to produce one semiconductor conduction type, e.g. p-channel or n-channel. A plurality of alternating crystalline or single crystal layers 404 of rare earth insulator are disposed between crystalline or single crystal layers 406 of Si₍₁₋ₓ₎Ge₍ₓ₎. Each of the layers 404 and 406 are approximately 1000 angstroms thick and provide strain matching or are substantially crystallographically matched to reduce strain between adjacent layers. Layers 404 and 406 cooperate to form a Distributed Bragg Reflector (DBR), which is deposited directly on the surface of silicon substrate or solar cell 400 and is specifically designed to reflect radiation back onto substrate or solar cell 400. For example, each of layers 404 and 406 are generally approximately one fourth wavelength (λ/4) thick at the wavelength of radiation to be absorbed. Also, as explained above, layers 404 can be chosen to up convert or down convert incident radiation to further enhance absorption in substrate or solar cell 400.

A crystalline or single crystal layer 408 of Silicon/germanium is epitaxially deposited on the upper surface of the DBR. The materials of layer 408 are provided in a mix or alloy of Si₍₁₋ₓ₎Ge₍ₓ₎. Preferably, the material of layer 408 is Si_{0.9}Ge_{0.1}. or a mix commensurate with layer 402 Also, layer 408 is doped, opposite to layer substrate or solar cell 400, to produce a second semiconductor conduction type, e.g. n-channel or p-channel. Thus, layers 400, 404, 406, and 408 cooperate to form a semiconductor diode that can be used to incorporate the cell into any of the structures illustrated and described above.

Thus, a horizontal active solar concentrator is disclosed that greatly extends the converting capabilities of a solar module while reducing the cost and complexity to a minimum. The active solar concentrator can be formed in a variety of configurations but is oriented in the horizontal plane to collect the most sunlight for a given area. Further, in the preferred embodiment, rare earth is included in the various reflectors to provide up-conversion of sunlight that is outside the conversion spectrum for silicon solar cells and the reflectors are adjusted in position and angle to provide the greatest lateral guiding and, thus, the more up-conversion.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. An active solar concentrator comprising:
a horizontally oriented structure including light directing portions with partially reflective surfaces directing light vertically impinging thereon into a central area; and
a solar module positioned in the central area to receive light from the partially reflective surfaces.

2. An active solar concentrator as claimed in claim 1 wherein the light directing portions include partially reflective surfaces oriented to receive light vertically from above and to redirect the received light horizontally toward the central area of the concentrator.

3. An active solar concentrator as claimed in claim 1 wherein the light directing portions are formed of material transparent to sunlight.

4. An active solar concentrator as claimed in claim 3 wherein the material transparent to sunlight includes one of glass or plastic.

5. An active solar concentrator as claimed in claim 1 wherein the solar module is sensitive to a portion of the sunlight and the partially reflective surfaces are formed of material transparent to the portion of sunlight to which the solar module is sensitive.

6. An active solar concentrator as claimed in claim 1 wherein the horizontally oriented structure has one of a generally round or generally rectangular configuration.

7. An active solar concentrator as claimed in claim 1 wherein the solar module includes a plurality of multi junction solar cells.

8. An active solar concentrator as claimed in claim 7 wherein the plurality of multi junction solar cells are formed on a common substrate.

9. An active solar concentrator as claimed in claim 8 wherein the plurality of multi junction solar cells formed on a common substrate include the greatest number of solar cells for the lowest cost per area.

10. An active solar concentrator as claimed in claim 1 wherein the solar module includes a rare earth single crystal up-conversion device positioned to enhance solar conversion in the solar module.

11. An active solar concentrator as claimed in claim 10 wherein the rare earth single crystal up-conversion device includes a Distributed Bragg Reflector.

12. An active solar concentrator as claimed in claim 10 wherein the Distributed Bragg Reflector includes electrically doped areas positioned to form a semiconductor diode coupled to the solar module.

13. An active solar concentrator as claimed in claim 10 wherein the Distributed Bragg Reflector includes crystallographically matched layers reducing strain between the Distributed Bragg Reflector and the solar module.

14. An active solar concentrator as claimed in claim 1 wherein the light directing portions include rare earth single crystal up-conversion layers

15. An active solar concentrator comprising:
a horizontally oriented structure including light directing portions surrounding and defining a central area, each light directing portion including at least one layer of rare earth oxide designed to up-convert light passing therethrough, and each light directing portion including a reflective surface oriented to receive light vertically from above and to redirect the received light horizontally toward the central area; and
a solar module positioned in the central area to receive light from the partially reflective surfaces and light passing through the rare earth oxide layers.

16. An active solar concentrator as claimed in claim 15 wherein the light directing portions are formed of material transparent to sunlight.

17. An active solar concentrator as claimed in claim 15 wherein the solar module includes a plurality of multi junction solar cells formed on a common substrate.

18. An active solar concentrator as claimed in claim 15 wherein the solar module is sensitive to a portion of the sunlight and the light directing portions are formed of material transparent to the portion of sunlight to which the solar module is sensitive.

19. An active solar concentrator as claimed in claim 15 wherein the horizontally oriented structure has one of a generally round or generally rectangular configuration.

20. An active solar concentrator as claimed in claim 15 wherein the solar module includes a rare earth single crystal up-conversion and/or down-conversion device positioned to enhance solar conversion in the solar module.

21. An active solar concentrator as claimed in claim 20 wherein the rare earth single crystal up-conversion and/or down-conversion device includes a Distributed Bragg Reflector.

22. An active solar concentrator as claimed in claim 21 wherein the Distributed Bragg Reflector includes electrically doped areas positioned to form a semiconductor diode coupled to the solar module.

23. An active solar concentrator as claimed in claim 21 wherein the Distributed Bragg Reflector includes crystallographically matched layers reducing strain between the Distributed Bragg Reflector and the solar module.

24. An active solar concentrator comprising:
a base structure including light directing portions surrounding and defining a central area, each light directing portion including at least one layer of rare earth oxide designed to up-convert light passing therethrough, each light directing portion including a reflective surface oriented to receive light vertically from above and to redirect the received light horizontally toward the central area, and the light directing portions being further positioned around the central area in a generally outwardly radiating orientation with the reflective surfaces of outer light directing portions directing reflected light inwardly toward a next adjacent light directing portion closer to the central area, each light directing portion receiving the inwardly directed light from an adjacent outer light directing portion through the at least one layer of rare earth oxide; and
a solar module positioned in the central area to receive light from the partially reflective surfaces and light passing through the rare earth oxide layers.
